(19) United States
(12) Patent Application Publication
(10) Pub. No.: US 2005/0145838 A1
(43) Pub. Date: Jul. 7, 2005

(54) Vertical Carbon Nanotube Field Effect Transistor

(75) Inventors: Toshiharu Furukawa, Essex Junction, VT (US); Steven J. Holmes, Guilderland, NY (US); Mark C. Hakey, Fairfax, VT (US); David V. Horak, Essex Junction, VT (US); Charles W. Koburger III., Delmar, NY (US); Peter H. Mitchell, Jericho, VT (US); Larry A. Nesbit, Williston, VT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 10/707,726

(22) Filed: Jan. 7, 2004

(51) Int. Cl. H01L 29/06

(52) U.S. Cl. 257/20

(57) ABSTRACT

A field effect transistor employs a vertically oriented carbon nanotube as the transistor body, the nanotube being formed by deposition within a vertical aperture, with an optional combination of several nanotubes in parallel to produced quantized current drive and an optional change in the chemical composition of the carbon material at the top or at the bottom to suppress short channel effects.

### BACKGROUND OF INVENTION

### TECHNICAL FIELD

The field of the invention is that of integrated circuit fabrication, in particular forming field effect transistors (FETs) using carbon nanotubes to provide the body of the FET.

It has been established that carbon nanotubes with the proper molecular structure may act as semiconductors.

Some attempts have been made to fabricate FETs using a carbon nanotube as the body of the transistor.

There have been problems in such attempts with producing FETs with well controlled channel lengths. As those skilled in the art are aware, variation in channel length affects the capacitance of the transistors and thus the timing of the transistor action.

Also, due to the difficulty of manipulating carbon nanotubes and due to the difficulty of controlling the growth of carbon nanotubes parallel to a wafer/substrate surface, the gate is usually the silicon wafer/substrate and the insulator is an oxide grown on the surface of the silicon wafer.

The results of such attempts, though they demonstrate that carbon nanotubes may be used as the transistor body, produce primarily experimental devices, not suited to mass production.

A potential benefit of FETs based on nanotubes is that they have very small diameters, approximately 5-50 nm and thus can theoretically be very closely packed.

Close packing has the very great potential benefit of Increasing the density of devices—a highly desirable result.

### SUMMARY OF INVENTION

The invention relates to a FET having a vertical carbon nanotube as the transistor body.

A feature of the invention is the use of a layer of deposited conductive material as the transistor gate, thereby establishing close control over the channel length that does not depend on lithography.

Another feature of the invention is the formation of an aperture within the gate layer, followed by deposition of a gate insulator on the walls of the aperture, and deposition of a nanotube within the aperture.

Another feature of the invention is the use of a lateral conductive layer as the transistor source and drain.

### BRIEF DESCRIPTION OF DRAWINGS

FIG. 1 shows a section of an integrated circuit containing a completed carbon-nanotube FET according to the invention.

FIG. 2 shows the same area at a preliminary step, before patterning the deposited layers.

FIG. 3 shows the same area after processing to expose steps for the formation of a source contact.

FIG. 4 shows the area after etching a via through the gate conductor layer.

FIG. 5 shows the area after deposition of a catalytic layer to promote the formation of the desired molecular structure within the nanotube.

FIG. 6 shows the area after forming the gate insulator.

FIG. 7 shows the area after formation of the carbon nanotube within the aperture.

FIG. 8 shows the area after deposition of insulating layers enclosing the FET structure.

FIG. 9 shows the area after formation of contacts to the transistor source, drain and gate.

### DETAILED DESCRIPTION

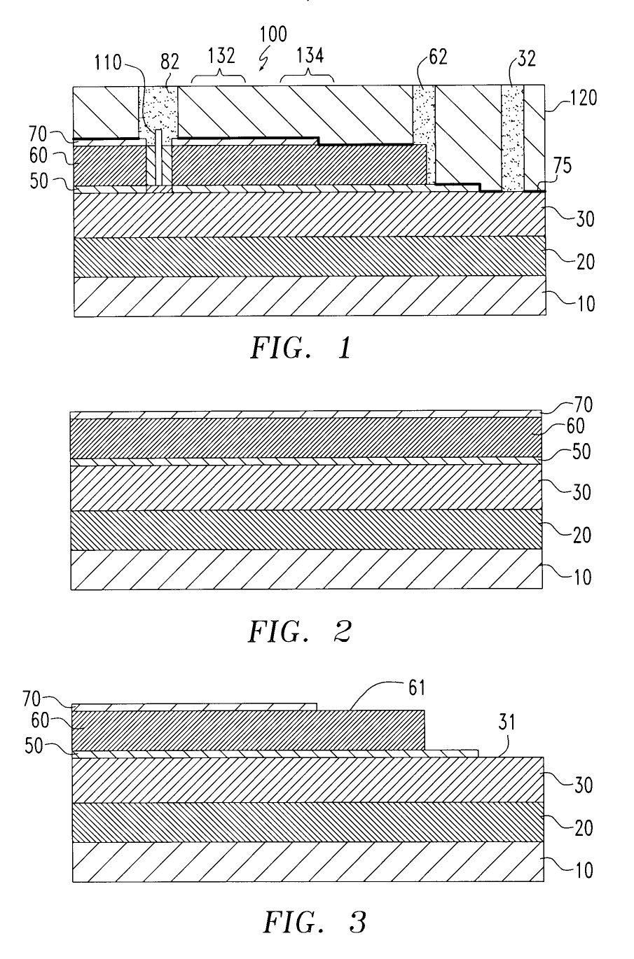

FIG. 1 shows a completed vertical carbon-nanotube FET 100 according to the invention. The whole structure rests on substrate 10, illustratively a silicon wafer conventionally used for integrated circuit fabrication. Silicon will not be required in general, unless other portions of the circuit use silicon transistors or other structures that make use of the well known properties of silicon.

Advantageously, silicon wafers are readily available and are provided with a very high degree of planarity. Other substrate materials, such as glass, may also be used if preferred.

An optional insulator layer 20, illustratively silicon oxide (SiO₂), serves to provide isolation between the transistor being formed and other areas of the wafer. If the substrate is insulating, layer 20 would not be required.

Conductor 30, illustratively doped polycrystalline silicon, is used to provide a contact and one electrode of the transistor. This layer and other layers in the structure illustrated are shown as extending across the Figure, for convenience is forming the illustration. A commercial embodiment would have the various horizontal layers patterned to save space and increase the density of devices in the circuit.

Layer 50, illustratively an insulator such as oxide or nitride (Si₃N₄), provides isolation between source 30 and gate 60 at the center of the Figure. As will be discussed below, gate 60 and the underlying layers are provided with a high degree of planarity, so that the thickness of layer 60 is highly uniform across the circuit. The uniformity in thickness translates to a corresponding uniformity in channel length in the devices.

On the left of the Figure, a carbon nanotube 110 extends vertically, separated from gate layer 60 by gate insulator 65.

Above layer 60, insulating layer 70 is the counterpart to layer 50, separating the gate electrode from the drain electrode.

Drain electrode 82 makes electrical contact with the top portion of tube 110 above gate 60, which is the drain of the FET.

For convenience in illustration, the three contacts to the source, drain and gate have been shown as passing through the same plane. In actual devices, they will be placed, as a result of various design choices, to maximize the packing density and minimize the capacitance between the source or drain and the gate, for example. Thus, the device designer may choose to have the various electrodes extend to the left in the figure or in or out of the plane of the paper.

FIG. 2 shows a starting structure for the practice of the invention, in which a silicon substrate 10 has been provided with a layer of insulator 20, illustratively silicon oxide (SiO₂), a conductive layer 30 that will be the source of the transistor, illustratively doped polycrystalline silicon (poly), a second, relatively thin layer of insulator 50, illustratively another layer of oxide or nitride (Si₃N₄), a gate conductor layer 60, illustratively poly, and a second layer of insulator 70.

Preferably, each layer of the structure has been planarized, e. g. by chemical-mechanical polishing, at least up to the top of layer 60. As will be discussed below, the channel length of the transistors will be set by the thickness of gate conductor layer 60, so that variations in the thickness of that layer will produce corresponding variations in channel length. Variations in the thickness of the underlying layers will also produce variations in channel length.

The Figures are partially pictorial and partially schematic in nature. The thicknesses shown in the figures are chosen for convenience in illustration and do not necessarily reflect the actual relative dimensions of the various layers.

Preferably, the layers 50 and 70 are relatively thin, consistent with providing an adequate degree of insulation, as they separate the transistor channel from the source and drain electrodes and serve to limit the current provided by the transistor.

FIG. 3 shows the next step in the process, in which standard lithographic and etch techniques have been used to form two steps that will be used for contacts to the electrodes. On the right, a location for the source contact is denoted with numeral 31. Above and to the left, a corresponding location 61 has been formed for the gate contact.

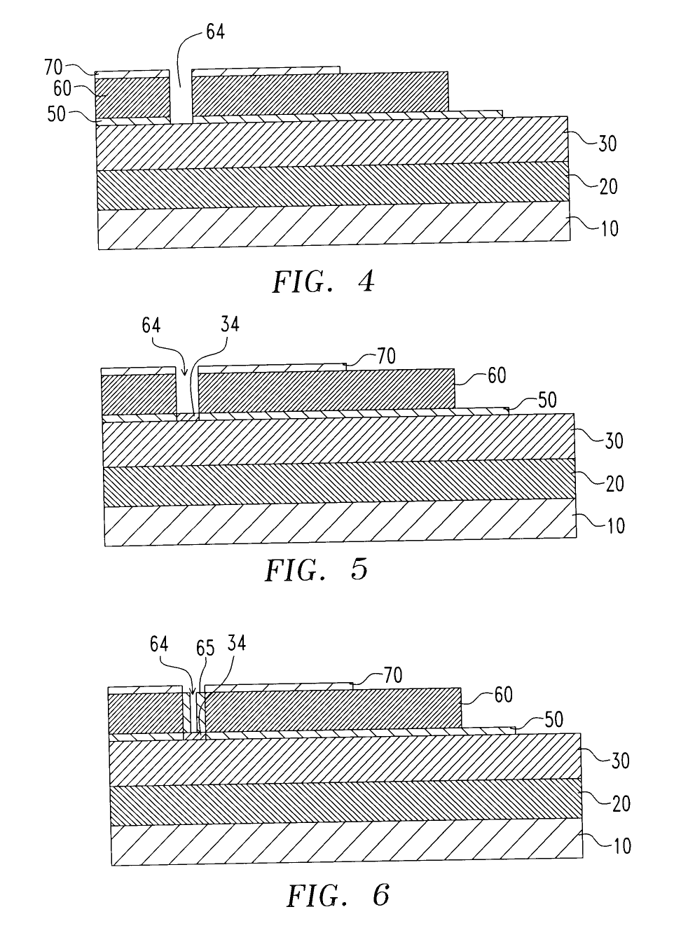

FIG. 4 shows the preparation of the location of the carbon nanotube. A via 64 has been formed through insulator 70, gate electrode 60 and insulator 50, penetrating layer 30 enough to establish a good contact and also such that the following catalytic material to be deposited next has a top surface that is below the bottom surface of insulator layer 50.

FIG. 5 shows the optional deposition of a catalyst 34, that has been found to initiate the growth of a carbon nanotube of the correct molecular structure. If the material of source layer 30 is suitable for the growth of a carbon nanotube, the catalyst may be omitted. In the case of establishing a semiconductor material, suitable catalytic materials are Ni, Co, Fe or silicides of these metals. Illustratively, the material is deposited by a CVD or PVD process. A wet etch or an isotropic dry etch is then used to clean off the catalytic material from the inner surface of layer 50, in order to assure that a residual amount of the catalyst does not short the source electrode to the gate. If the catalyst is a good insulator, this last step may be omitted.

FIG. 6 shows the result of forming a gate insulating layer 65 on the interior surface of aperture 64. When the gate layer 60 is poly, it is convenient to oxidize thermally the interior surface of aperture 64 to form gate insulator 65. If the catalyst cannot stand the oxidation temperature, it may be deposited later after oxidation and a directional reactive ion etch (RIE) to form a clean surface at the bottom of aperture 64. Those skilled in the art will be aware of other alternatives, such as a nitride gate insulator or another insulating material that may be deposited within the aperture at a lower temperature, in the event that the gate conductor material does not form a suitable oxide or if the oxidation temperature is too high for the catalyst.

An advantage of a deposited gate insulator is that it will extend continuously up past the top surface of the gate and into the interior of insulator layer 70, thus preventing any shorts between the gate and the carbon.

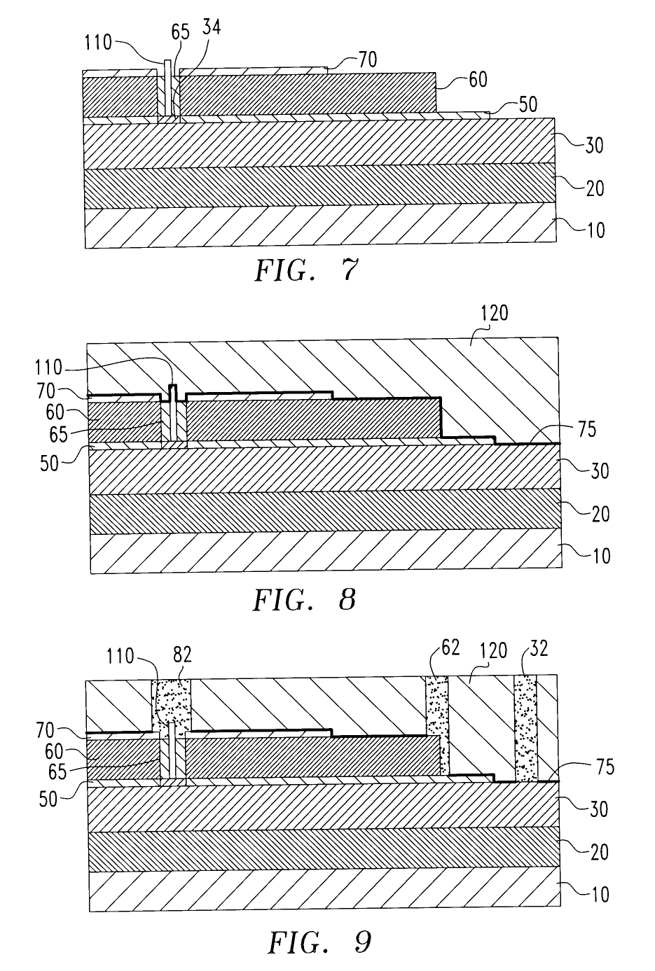

FIG. 7 shows the structure after formation of the carbon nanotube 110, shown as extending slightly up above the top of insulator 70. Illustratively, the carbon nanotube is formed by reacting C₂H₂+N₂.

FIG. 8 shows the structure after deposition of a nitride barrier layer 75 and a BPSG interlevel dielectric 120.

Referring back to FIG. 1, there is shown the result of forming vias to the source, gate and carbon and filling the vias with the conductive interconnect used for the circuit, e. g. copper.

Brackets 132 and 134 in FIG. 1 indicate locations of additional nanotubes connected in parallel between the same source and drain and controlled by the same gate. Those skilled in the art will be aware that transistors having discrete amounts of current capacity may be formed by connecting two or more nanotubes in parallel, depending on the load being driven.

Conventional back end processes form other interconnection layers as required to complete the circuit.

Those skilled in the art will appreciate that current technology permits the gate layer to be formed with a thickness in the range of 5-200 nm and a tolerance of about 2%-5%, three sigma. This provides a more uniform transistor channel length across a circuit than is practical with lithographic techniques.

The thickness of insulating layers 50 and 70 are preferably less than 5-50 nm in order to reduce the effect of having a length of higher-resistance material in series with the transistor electrodes.

The diameter of the aperture 64 is preferably about 5-70 nm and the thickness of the walls of the carbon nanotube is preferably about 2-50 nm.

If desired, the chemical composition of the carbon nanotubes at the ends that meet the source and/or drain contacts may be varied, thus producing the same benefits as are currently realized by the LDD and halo implants used in planar FETs (e.g. suppressing short channel effects). Since the transistor body is being formed in a sequential process, it is convenient to alter the composition of only the source or only the drain interface regions to meet the device requirements. This is in contrast to the planar technology that requires implanting both ends of the channel.

While the invention has been described in terms of a single preferred embodiment, those skilled in the art will recognize that the invention can be practiced in various versions within the spirit and scope of the following claims.

1. A method of forming an integrated circuit an a substrate, having a set of vertical field effect transistors having a channel in a carbon nanotube, comprising the steps of:
forming a first conductive layer on a substrate;
forming a first insulating layer on said first conductive layer; and
forming a gate layer, having a gate layer thickness within a thickness tolerance, on said first insulating layer;
forming a set of apertures, having substantially vertical interior walls, through said gate layer and said first insulating layer, the bottom of said apertures exposing said first conductive layer;
forming an insulating liner on said walls of said apertures;
forming a set of semiconductive carbon nanotubes in said apertures by introducing a chemical constituent into the nanotube material during formation of only one of the top and bottom of the nanotube to produce an electrical effect during operation, the bottom of said carbon nanotubes being in electrical contact with said first conductive layer; and
forming an electrical contact on a top of said carbon nanotubes.

2. A method according to claim 1, further comprising the steps of:
forming a set of at least two apertures through said gate layer and connecting the bottoms of the set of carbon nanotubes in said set of apertures in parallel to said first conductive layer, thereby forming a set of FETs having a common electrode in said first conductive layer and a common gate electrode.

3. A method according to claim 1, further comprising the steps of:
forming a layer of catalyst on said bottom of said aperture, such that said catalyst initiates the growth of a semiconductor carbon nanotube.

4. A method according to claim 1, further comprising the steps of:
forming said insulating liner by thermally oxidizing said gate layer.

5. A method according to claim 1, further comprising the steps of:
forming said insulating liner by chemical vapor deposition.

6. (canceled)

7. A method according to claim 1, in which said chemical constituent is introduced to suppress short channel effects during transistor operation.

8. A method according to claim 2, further comprising the steps of:
forming a layer of catalyst on said bottom of said aperture, such that said catalyst initiates the growth of a semiconductor carbon nanotube.

9. A method according to claim 2, further comprising the steps of:
forming said insulating liner by thermally oxidizing said gate layer.

10. A method according to claim 2, further comprising the steps of:
forming said insulating liner by chemical vapor deposition.

11-14. (canceled)

15. A method according to claim 3, further comprising the steps of:
introducing a chemical constituent into the nanotube material during formation of one of the top and bottom of the nanotube to produce an electrical effect during operation.

16. A method according to claim 15, in which said chemical constituent is introduced to suppress short channel effects during transistor operation.

17. A vertical field effect transistor having a channel in a carbon nanotube, comprising:
a first conductive layer disposed on a substrate;
a first insulating layer disposed on said first conductive layer; and
a gate layer disposed on said first insulating layer;
an aperture, having substantially vertical interior walls, extending through said gate layer and said first insulating layer, the bottom of said aperture exposing said first conductive layer;
an insulating liner on said walls of said aperture;
a semiconductive carbon nanotube in said aperture, the bottom of said carbon nanotube being in electrical contact with said first conductive layer; and
an electrical contact formed on a top of said carbon nanotube.

18. A transistor according to claim 17, further comprising: a set of at least two apertures through said gate layer, the bottoms of the set of carbon nanotubes in said set of apertures being connected in parallel to said first conductive layer, thereby forming a set of FETs having a common electrode in said first conductive layer and a common gate electrode.

19. A transistor according to claim 17, further comprising: a layer of catalyst on said bottom of said aperture, such that said catalyst initiates the growth of a semiconductor carbon nanotube.

20. A transistor according to claim 17, further comprising: a chemical constituent introduced into the nanotube material during formation of one of the top and bottom of the nanotube to produce an electrical effect during operation.
